(19) United States
(12) Patent Application Publication
(10) Pub. No.: US 2025/0374751 A1
(43) Pub. Date: Dec. 4, 2025

(54) DISPLAY DEVICE AND MANUFACTURING METHOD THEREOF

(71) Applicant: Samsung Display Co., LTD., Yongin-si (KR)

(72) Inventor: YOON HO KANG, Yongin-si (KR)

(21) Appl. No.: 18/947,858

(22) Filed: Nov. 14, 2024

(30) Foreign Application Priority Data
Jun. 4, 2024 (KR) 10-2024-0072778

(51) Int. Cl. H10K 50/17; H10K 50/115; H10K 50/16; H10K 59/12; H10K 59/122; H10K 71/60

(52) U.S. Cl. CPC H10K 50/171; H10K 50/115; H10K 50/16; H10K 59/1201; H10K 59/122; H10K 71/60

(57) ABSTRACT

A display device includes: a substrate; a circuit layer disposed on the substrate; a plurality of first electrodes disposed on the circuit layer and spaced apart from each other; a pixel defining film disposed on the circuit layer and disposed to cover an area between the first electrodes in a plan view; a conductive layer disposed to overlap with the pixel defining film in the plan view; an electron functional layer disposed on the first electrodes and covering the first electrodes in the plan view and in direct contact with the conductive layer; a light-emitting layer disposed on the electron functional layer; and a second electrode disposed on the light-emitting layer.

This application claims priority to Korean Patent Application No. 10-2024-0072778, filed on Jun. 4, 2024, and all the benefits accruing therefrom under 35 U.S.C. § 119, the content of which in its entirety is herein incorporated by reference.

### BACKGROUND

### 1. Technical Field

The present disclosure relates to a display device and a manufacturing method thereof, specifically, to a display device having improved light-emitting efficiency and a method of manufacturing such a display device.

### 2. Description of the Related Art

The display device is provided with a light-emitting diode, which includes a hole injection electrode, an electron injection electrode and a light-emitting layer formed therebetween. The self-emitting display device generates light as excitons, which are created by the combination of holes injected from the hole injection electrode and electrons injected from the electron injection electrode in the light-emitting layer, transition from an excited state to a ground state.

To improve the luminous efficiency of display devices, studies have been conducted on acid treatment processes for an electron functional layer included between the electron injection electrode and the light-emitting layer.

### SUMMARY

The present disclosure provides a display device having improved light-emitting efficiency. The present disclosure also provides a method of manufacturing a display device having improved light-emitting efficiency.

An aspect of the present disclosure provides a display device including a substrate, a circuit layer, first electrodes, a pixel defining film, a conductive layer, an electron functional layer, a light-emitting layer and a second electrode. The circuit layer is disposed on the substrate.

The first electrodes are disposed on the circuit layer and spaced apart from each other. The pixel defining film is disposed on the circuit layer and disposed to cover the first electrodes in a plan view. The conductive layer is disposed to overlap with the pixel defining film in the plan view.

The electron functional layer is disposed on the first electrodes and covers the first electrodes in the plan view and is in direct contact with the conductive layer. The light-emitting layer is disposed on the electron functional layer. The second electrode is disposed on the light-emitting layer.

In an embodiment of the present disclosure, the conductive layer may include metal.

In an embodiment, the conductive layer may include at least one of a silver-magnesium (AgMg) alloy or silver (Ag).

In an embodiment, the electron functional layer may include metal oxide.

In an embodiment, the electron functional layer may include at least one of an electron injection layer including zinc oxide (ZnO) or an electron transport layer including zinc-magnesium oxide (ZnMgO).

In an embodiment, the electron injection layer and the electron transport layer may each have an integrated shape.

In an embodiment of the present disclosure, the conductive layer may be interposed between the pixel defining film and the electron functional layer and may directly contact the pixel defining film and the electron functional layer.

In an embodiment, the pixel defining film may include a first pixel defining film and a second pixel defining film. The first pixel defining film may be disposed on the first electrodes and may cover the area between the first electrodes in the plan view. The second pixel defining film may be disposed on the first pixel defining film and the electron functional layer and may overlap with the first pixel defining film in the plan view. The conductive layer may be interposed between the first pixel defining film and the second pixel defining film.

In an embodiment, the conductive layer may be interposed between the first pixel defining film and the electron functional layer and may directly contact the first pixel defining film and the electron functional layer.

In an embodiment, the conductive layer may be interposed between the electron functional layer and the second pixel defining film and may directly contact the electron functional layer and the second pixel defining film.

In an embodiment of the present disclosure, the pixel defining film may be provided in plurality in the plan view, the conductive layer may include a first conductive layer and a second conductive layer that are disposed on different pixel defining films of the plurality of pixel defining films, And the first conductive layer and the second conductive layer may have different thicknesses from each other.

In another embodiment of the present disclosure, the pixel defining film may be provided in plurality in the plan view, and the conductive layer may overlap with one or more of the plurality of pixel defining films and may not overlap with the other pixel defining films of the plurality of pixel defining films in the plan view.

In an embodiment, the light-emitting layer may include a quantum dot.

Another aspect of the present disclosure provides a method of manufacturing a display device that includes preparing a substrate, forming a circuit layer, forming first electrodes, forming an electron functional layer, forming a pixel defining film, forming a conductive layer, acid treating the electron functional layer, forming a light-emitting layer and forming a second electrode. The preparing of the substrate includes preparing a substrate defined with a light-emitting area and a non-light-emitting area. In the forming of the circuit layer, the circuit layer is formed on the substrate. In the forming of the first electrodes, the first electrodes are formed on the circuit layer to correspond to the light-emitting area. In the forming of the electron functional layer, the electron functional layer is formed to cover the first electrodes in a plan view. In the forming of the pixel defining film, the pixel defining film is formed to correspond to the non-light-emitting area and to cover an area between the first electrodes. In the forming of the conductive layer, the conductive layer is formed to correspond to the area between the first electrodes. In the acid treating, the electron functional layer is acid treated. In the forming of the light-emitting layer, the light-emitting layer is formed on the electron functional layer. In the forming of the second electrode, the second electrode is formed on the light-emitting layer.

In an embodiment of the present disclosure, the forming of the light-emitting layer may be performed after the acid treating of.

In an embodiment of the present disclosure, the conductive layer may be formed using silver (Ag) or an AgMg alloy.

According to an embodiment of the present disclosure, the forming of the electron functional layer may include forming an electron injection layer using ZnO and forming an electron transport layer using ZnMgO.

In an embodiment, the forming of the conductive layer may be performed after the forming of the electron functional layer. The acid treating of may be performed after the forming of the conductive layer. The forming of the pixel defining film may be performed after the acid treating of the electron functional layer. The conductive layer may be formed to directly contact the electron functional layer and the pixel defining film.

In another embodiment of the present disclosure, the forming of the pixel defining film may include forming a first pixel defining film and forming a second pixel defining film. The forming of the first pixel defining film may be performed after the forming of the first electrodes. The forming of the conductive layer may be performed after the forming of the first pixel defining film. The forming of the electron functional layer may be performed after the forming of the conductive layer. The forming of the second pixel defining film may be performed after the acid treating of the electron functional layer.

Yet another aspect of the present disclosure provides a display device including a substrate, a circuit layer, first electrodes, a pixel defining film, a conductive layer, an electron functional layer, a light-emitting layer and a second electrode. The circuit layer is disposed on the substrate. The first electrodes are disposed on the circuit layer and are spaced apart from each other. The pixel defining film is disposed on the circuit layer and disposed to cover the first electrodes. The conductive layer is disposed to overlap with the pixel defining film in the plan view. The electron functional layer is disposed on the first electrodes and covers the first electrodes in the plan view. The light-emitting layer is disposed on one of the first electrodes. The second electrode is disposed to face the first electrodes with the light-emitting layer therebetween. The conductive layer includes at least one of an AgMg alloy or silver (Ag). The electron functional layer includes an electron injection layer containing ZnO. The electron functional layer includes an electron transport layer disposed on the electron injection layer and containing ZnMgO.

According to one or more embodiments of the present disclosure, the acid treatment efficiency of the electron functional layer is effectively improved by the conductive layer included in a light-emitting diode layer, thereby providing a display device with enhanced light-emitting efficiency and a method of manufacturing the same.

### BRIEF DESCRIPTION OF THE DRAWINGS

These and/or other features will become apparent and more readily appreciated from the following description of the embodiments, taken in conjunction with the accompanying drawings in which:

FIG. 1 is a plan view illustrating a display device in accordance with an embodiment of the present disclosure;

FIG. 2 is a cross-sectional view of the display device in accordance with an embodiment of the present disclosure taken along line I-I′ line of FIG. 1;

FIG. 3 is an enlarged view of an area demarcated with AA in FIG. 2;

FIG. 4 is a cross-sectional view of a display device according to another embodiment of the present disclosure;

FIG. 5 is a cross-sectional view of a display device according to still another embodiment of the present disclosure;

FIG. 6 is a cross-sectional view of a display device according to yet another embodiment of the present disclosure;

FIG. 7 is a cross-sectional view of a display device according to still another embodiment of the present disclosure;

FIG. 8 is a cross-sectional view of a display device according to yet another embodiment of the present disclosure;

FIG. 9 is a flow diagram illustrating a method of manufacturing a display device according to an embodiment of the present disclosure;

FIGS. 10A through 10E are cross-sectional views sequentially illustrating a method of manufacturing a display device according to an embodiment of the present disclosure;

FIG. 11 is a cross-sectional view of an acid treatment apparatus according to an embodiment of the present disclosure;

FIG. 12 is a flow diagram illustrating a method of manufacturing a display device according to an embodiment of the present disclosure; and

FIGS. 13A through 13E are cross-sectional views sequentially illustrating a method of manufacturing a display device according to an embodiment of the present disclosure.

### DETAILED DESCRIPTION

References will now be made in detail to certain embodiments, of which examples are illustrated in the accompanying drawings, where like reference numerals refer to like elements throughout. The embodiments may have a variety of forms and permutations, but the present disclosure shall by no means be construed as being limited to the described embodiments. Rather, the present disclosure shall be construed to encompass all forms, permutations, equivalents and substitutes covered by the technical ideas and scope of the present disclosure. Accordingly, the embodiments are merely described below, by referring to the figures, to explain features of the present disclosure.

When an element is described to be “disposed on,” “placed on,” “arranged on,” “connected to,” or “coupled to” another element, it shall be construed as being disposed on, placed on, arranged on, connected to, or coupled to the other element directly but also as possibly having another element therebetween. On the other hand, if one element is described to be “directly disposed on,” “directly placed on,” “directly arranged on,” “directly connected to,” or “directly coupled to” another element, it shall be construed that there is no other element interposed therebetween.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements.

Terms such as “first” and “second” may be used in describing various elements, but the above elements shall not be restricted to the above terms. The above terms may be used only to distinguish one element from the other. For instance, the first element may be named the second element, and vice versa, without departing the scope of claims of the present disclosure. Unless clearly used otherwise, any expressions in a singular form may include a meaning of a plural form. The term “and/or” shall include the combination of a plurality of listed items or any of the plurality of listed items.

Moreover, relative terms, such as “below,” “beneath,” “lower,” “bottom,” “above,” “over,” “upper,” “top,” etc., may be used herein to describe one element's relationship to another element as illustrated in the accompanying figures. It shall be understood that relative terms are intended to encompass different orientations of the device in addition to the orientation depicted in the accompanying figures. For example, if the device in one of the figures is turned over, elements described as being on the “lower” side of the other elements would then be oriented on “upper” sides of the other elements. The exemplary term “lower” can therefore encompass an orientation of both “lower” and “upper,” depending on the particular orientation of the figure. Similarly, if the device in one of the figures is turned over, elements described as “below” or “beneath” other elements would then be oriented “above” the other elements. The exemplary term “below” or “beneath” can therefore encompass an orientation of both above and below.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

Unless otherwise defined, all terms, including technical terms and scientific terms, used herein have the same meaning as how they are generally understood by those of ordinary skill in the art to which the present disclosure pertains. Any term that is defined in a general dictionary shall be construed to have the same meaning in the context of the relevant art, and, unless otherwise defined explicitly, shall not be interpreted to have an idealistic or excessively formalistic meaning.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof. Hereinafter, certain embodiments of the present disclosure will be described with reference to the accompanying drawings.

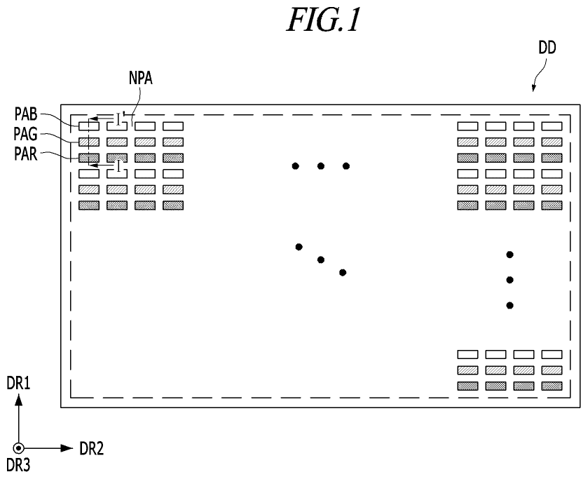

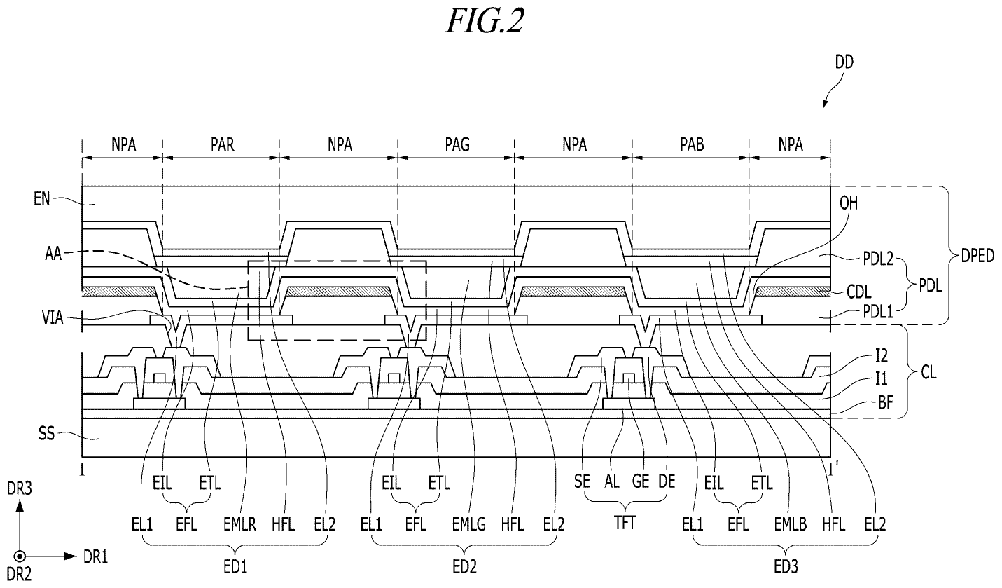

FIG. 1 is a plan view illustrating a display device in accordance with an embodiment of the present disclosure, and FIG. 2 is a cross-sectional view of the display device, taken along line I-I′ line of FIG. 1, in accordance with an embodiment of the present disclosure. As used herein, the “plan view” is a view in a thickness direction (i.e., the third direction DR3) of the substrate SS (See FIG. 2).

In an embodiment of the present disclosure, first to third directions DR1, DR2, DR3 may be defined, in which a first direction DR1 and a second direction DR2 may intersect with each other in directions flush with a display device DD illustrated in FIG. 1. A third direction DR3 may be in a direction of thickness of the display device DD illustrated in FIG. 2.

Referring to FIGS. 1 and 2, the display device DD in accordance with an embodiment of the present disclosure may have a plurality of light-emitting areas PAR, PAG, PAB and a non-light-emitting area NPA defined therein. The light-emitting areas PAR, PAG, PAB may include a red light-emitting area PAR, a green light-emitting area PAG and a blue light-emitting area PAB. The light-emitting areas PAR, PAG, PAB may be areas where an image is displayed.

In an embodiment of the present disclosure, the display device DD may include a substrate SS, a circuit layer CL disposed on the substrate SS and a light-emitting diode layer DPED disposed on the circuit layer CL.

The substrate SS may be a member providing a base plate on which the light-emitting diode layer DPED is disposed on. The substrate SS may be a glass substrate, a metal substrate or a plastic substrate. However, the substrate SS of the present embodiment is not limited to the above and may be an inorganic layer, an organic layer or a composite material layer.

The circuit layer CL may be disposed on the substrate SS. The circuit layer CL may include transistors TFT, which are configured to provide electric signals to light-emitting diodes ED1, ED2, ED3 disposed on the light-emitting diode layer DPED, a first insulating film I1 and a second insulating film I2.

The transistor TFT may include an active layer AL disposed on the substrate SS, a gate electrode GE disposed at least on a portion of the active layer AL, and a source electrode SE and a drain electrode DE disposed on the gate electrode GE and electrically connected to the active layer AL.

The first insulating film I1 may be interposed between the active layer AL and the gate electrode GE, and the second insulating film I2 may be disposed on the gate electrode GE.

In an embodiment of the present disclosure, the circuit layer CL may further include a buffer layer BF. The buffer layer BF may be interposed between the substrate SS and the active layer AL. The buffer layer BF may provide a reformed surface to have an enhanced adhesiveness to the transistor TFT. The buffer layer BF may be an inorganic layer containing at least one inorganic substance of silicon nitride, silicon oxide or silicon oxynitride.

The light-emitting diode layer DPED may include a pixel defining film PDL, a conductive layer CDL, light-emitting diodes ED1, ED2, ED3 and an encapsulation layer EN. Each of the light-emitting diodes ED1, ED2, ED3 may include a first electrode EL1, an electron functional layer EFL, light-emitting layers EMLR, EMLG, EMLB, a hole functional layer HFL and a second electrode EL2.

The pixel defining film PDL may be disposed on the circuit layer CL and may be disposed to cover an area between the first electrodes EL1 in a plan view. The pixel defining film PDL may be disposed to correspond to the non-light-emitting area NPA. The light-emitting areas PAR, PAG, PAB may be defined by the pixel defining film PDL. The pixel defining film PDL may be configured to classify the light-emitting diodes ED1, ED2, ED3. Moreover, the pixel defining film PDL may be an insulating film.

The pixel defining film PDL may be made of a polymer resin. For instance, the pixel defining film PDL may be formed by containing a polyacrylate-based resin or a polyimide-based resin. Moreover, the pixel defining film PDL may be formed by further containing inorganic materials in addition to the polymer resin. Meanwhile, the pixel defining film PDL may be formed by including a light-absorbing material or formed by including a black pigment or black dye. The pixel defining film PDL formed by including a black pigment or black dye may be implemented as a black pixel defining film. Used for the black pigment or black dye when forming the pixel defining film PDL may be, but not limited to, carbon black.

Moreover, the pixel defining film PDL may be made of an inorganic material. For instance, the pixel defining film PDL may be formed by including silicon nitride (SiNx), silicon oxide (SiOx), silicon oxynitride (SiOxNy), and the like.

In an embodiment of the present disclosure, the pixel defining film PDL may include a first pixel defining film PDL1 and a second pixel defining film PDL2. The first pixel defining film PDL1 may be disposed to cover an area between the first electrodes EL1 in a plan view and may be disposed on the edges of the first electrodes EL1. The second pixel defining film PDL2 may be disposed on the first pixel defining film PDL1 and may overlap with the first pixel defining film PDL1. The second pixel defining film PDL2 may be disposed on the electron functional layer EFL.

The conductive layer CDL may be interposed between the first electrodes EL1 and may be disposed to correspond to the non-light-emitting area NPA in a plan view. The conductive layer CDL may overlap with the pixel defining film PDL and, in an embodiment, may overlap with the first pixel defining film PDL1 and the second pixel defining film PDL2. In an embodiment, the conductive layer CDL may be disposed on the first pixel defining film PDL1. Specifically, the conductive layer CDL may contact an upper surface of the first pixel defining film PDL1. In FIG. 2, a lower surface of the conductive layer CDL is illustrated to have a same area as the upper surface of the first pixel defining film PDL1, but the present disclosure is not limited to what is illustrated in FIG. 2.

The conductive layer CDL may be formed through a separate patterning process from the pixel defining film PDL and thus may have a smaller area compared to the pixel defining film PDL and may have a shape that is completely covered. The conductive layer CDL may be insulated from the first electrode EL by the first pixel defining film PDL1. The conductive layer CDL may include a conductive material, specifically a metal. Preferably, the conductive layer CDL may include a silver-magnesium (AgMg) alloy or silver (Ag). The conductive layer CDL may be formed with a thickness ranging from 100 angstroms (Å) to 500 Å. The function of the conductive layer CDL will be described later.

The first electrode EL1 may be disposed on the circuit layer CL. The first electrode EL1 may have conductivity and may be electrically connected to the transistor TFT to receive an electrical signal. In an embodiment of the present disclosure, the first electrode EL1 may be a cathode.

The first electrode EL1 may be formed of a metallic material, a metal alloy or a conductive compound. The first electrode EL1 may be a transmissive electrode, a semi-transmissive electrode, or a reflective electrode. The first electrode EL1 may contain at least one selected from Ag, Mg, Cu, Al, Pt, Pd, Au, Ni, Nd, Ir, Cr, Li, Ca, LiF, Mo, Ti, W, In, Sn and Zn, a compound of two or more of these materials, a mixture of two or more of these materials, or an oxide of these materials.

In the case where the first electrode EL1 is a transmissive electrode, the first electrode EL1 may contain a transparent metal oxide, for example, indium tin oxide (“ITO”), indium zinc oxide (“IZO”), zinc oxide (ZnO) or indium tin zinc oxide (“ITZO”). In the case where the first electrode EL1 is a semi-transmissive electrode or a reflective electrode, the first electrode EL1 may contain Ag, Mg, Cu, Al, Pt, Pd, Au, Ni, Nd, Ir, Cr, Li, Ca, LiF/Ca (a laminated structure of LiF and Ca), LiF/Al (a laminated structure of LiF and Al), Mo, Ti, W or a compound or mixture of these materials (e.g., a mixture of Ag and Mg).

Alternatively, the first electrode EL1 may have a multilayer structure including a reflective film or a semi-transmissive film formed of the aforementioned materials and a transparent conductive film formed of indium tin oxide (ITO), indium zinc oxide (IZO), zinc oxide (ZnO), indium tin zinc oxide (ITZO), etc. For example, the first electrode EL1 may have a triple layer structure of ITO/Ag/ITO, but the present disclosure is not limited to this configuration.

Furthermore, the embodiment is not limited to the above description, and the first electrode EL1 may contain, for example, the above-described metallic materials, a combination of two or more materials selected from the above-described metallic materials, or an oxide of the above-described metallic materials.

The electron functional layer EFL may be disposed on the first electrode EL1 and may have a shape covering the first electrode EL1. In an embodiment of the present disclosure, the electron functional layer EFL may be arranged to contact the conductive layer CDL, but the embodiment is not limited to this arrangement.

The electron functional layer EFL may include at least one of an electron injection layer EIL or an electron transport layer ETL. In an embodiment illustrated in FIG. 2, the electron functional layer EFL is illustrated to include both the electron injection layer EIL and the electron transport layer ETL.

The electron injection layer EIL may be disposed on the first electrode EL1. In an embodiment illustrated in FIG. 2, the electron injection layer EIL may be disposed on the first electrode EL1 and the conductive layer CDL. The electron injection layer EIL may be formed as an integrated shape (i.e., monolithic structure), completely covering the first electrode EL1. Referring to FIG. 2, in an embodiment, the electron injection layer EIL can completely cover both the first electrodes EL1 and the conductive layer CDL. The electron injection layer EIL may be in contact with the first electrode EL1. Referring to FIG. 2, in an embodiment of the present disclosure, the electron injection layer EIL may be in contact with the first electrode EL1 and the conductive layer CDL. The material contained in the electron injection layer EIL may have higher electrical conductivity than the material contained in the electron transport layer ETL. In one embodiment, the electron injection layer EIL may include zinc oxide (ZnO).

The electron transport layer ETL may be disposed on the electron injection layer EIL. The electron transport layer ETL may be formed as an integrated shape (i.e., monolithic structure), completely covering the first electrodes EL1. Referring to FIG. 2, in an embodiment, the electron transport layer ETL may be formed as an integrated shape, completely covering the first electrode EL1 and the conductive layer CDL on the electron injection layer EIL. In an embodiment, the electron transport layer ETL may contain zinc-magnesium oxide (ZnMgO).

The light-emitting layers EMLR, EMLG, EMLB may be disposed on the electron functional layer EFL and may be arranged corresponding to the light-emitting areas PAR, PAG, PAB. The light-emitting areas PAR, PAG, PAB may be distinguished according to the color of light generated, respectively, by the light-emitting diodes ED1, ED2, ED3, which may include respective light-emitting layers EMLR, EMLG, EMLB. Nonetheless, the embodiment is not limited to what is described herein.

In an embodiment of the present disclosure, the light-emitting layers EMLR, EMLG, EMLB may include quantum dots.

In an embodiment of the present disclosure, the plurality of light-emitting diodes ED1, ED2, ED3 may emit light in the same wavelength range, or at least one of the plurality of light-emitting diodes ED1, ED2, ED3 may emit light in a different wavelength range. For example, all of the light-emitting diodes ED1, ED2, ED3 may emit blue light.

Meanwhile, in the case where all the light-emitting diodes ED1, ED2, ED3 emit blue light, the display device DD may further include a light control layer (not shown) disposed on the encapsulation layer EN. The light control layer (not shown) may be a layer containing a light converter such as quantum dots or phosphors. The light control layer (not shown) may include a first light control portion, which corresponds to the red light-emitting area PAR and is configured to convert blue light to red light, and a second light control portion, which corresponds to the green light-emitting area PAG and is configured to convert blue light to green light.

Although it is illustrated in FIGS. 1 and 2 that the light-emitting areas PAR, PAG, PAB have similar areas, the embodiment is not limited to what is illustrated herein, and the light-emitting areas PAR, PAG, PAB may have different areas depending on the wavelength range of the light being emitted. Here, the areas of the light-emitting areas PAR, PAG, PAB may refer to areas seen on a plane defined by the first direction DR1 and the second direction DR2.

Meanwhile, the arrangement of the light-emitting areas PAR, PAG, PAB is not limited to what is illustrated in FIG. 1, and the order in which the light-emitting area PAR, the green light-emitting area PAG and the blue light-emitting area PAB are arranged may be combined and provided in a variety of ways depending on the characteristics of the display quality required by the display device DD. For example, the arrangement of the light-emitting areas PAR, PAG, PAB may be in a PENTILE™ arrangement or a Diamond Pixel™ arrangement.

Moreover, the areas of the light-emitting areas PAR, PAG, PAB may be different from one another. For instance, in an embodiment, the area of the green light-emitting area PAG may be smaller than the area of the blue light-emitting area PAB, but the embodiment is not limited to this configuration.

The hole functional layer HFL may include at least one of a hole injection layer or a hole transport layer. The hole functional layer HFL may be constituted with a single layer or a multilayer structure having a plurality of layers. The hole functional layer HFL may be disposed on the light-emitting layers EMLR, EMLG, EMLB and may correspond to the light-emitting areas PAR, PAG, PAB.

The hole functional layer HFL may be formed using an inkjet printing technique. It is illustrated as an example in FIG. 2 that the hole functional layer HFL is provided within an area defined by the second pixel defining film PDL2. Yet, the present disclosure is not limited to what is illustrated in FIG. 2, and the hole functional layer HFL may be provided within an area defined by the first pixel defining film PDL1. Moreover, it is possible that the hole functional layer HFL is formed on an entire surface through a deposition process.

The second electrode EL2 is disposed on the light-emitting layers EMLR, EMLG, EMLB. The second electrode EL2 may face opposite to the first electrode EL1. The second electrode EL2 may have an integrated shape that is extended from the light-emitting areas PAR, PAG, PAB to non-light-emitting area NPA. The second electrode EL2 may be a common electrode. In one embodiment, the second electrode EL2 may be an anode.

The second electrode EL2 may contain at least one selected from Ag, Mg, Cu, Al, Pt, Pd, Au, Ni, Nd, Ir, Cr, Li, Ca, LiF, Mo, Ti, W, In, Sn and Zn, a compound of two or more of these materials, a mixture of two or more of these materials, or an oxide of these materials.

The second electrode EL2 may be a transmissive electrode, a semi-transmissive electrode, or a reflective electrode. In the case where the second electrode EL2 is a transmissive electrode, the second electrode EL2 may be constituted with a transparent metal oxide, for example, indium tin oxide (ITO), indium zinc oxide (IZO), zinc oxide (ZnO), indium tin zinc oxide (ITZO).

In the case where the second electrode EL2 is a semi-transmissive electrode or a reflective electrode, the second electrode EL2 may contain Ag, Mg, Cu, Al, Pt, Pd, Au, Ni, Nd, Ir, Cr, Li, Ca, LiF/Ca, LiF/Al, Mo, Ti, Yb, W or a compound or mixture of these materials (e.g., AgMg, AgYb or MgAg). Alternatively, the second electrode EL2 may have a multilayer structure including a reflective film or a semi-transmissive film formed of the aforementioned materials and a transparent conductive film formed of indium tin oxide (ITO), indium zinc oxide (IZO), zinc oxide (ZnO), indium tin zinc oxide (ITZO), etc. For example, the second electrode EL2 may contain, for example, the above-described metallic materials, a combination of two or more materials selected from the above-described metallic materials, or an oxide of the above-described metallic materials.

Although not illustrated, the second electrode EL2 may be connected with an auxiliary electrode. By having the second electrode connected with the auxiliary electrode, the resistance of the second electrode EL2 may be reduced.

The encapsulation layer EN may be configured to seal off the light-emitting diodes ED1, ED2, ED3 to protect the light-emitting diodes ED1, ED2, ED3 from moisture, oxygen, and/or foreign substances. The encapsulation layer EN may be constituted with a single layer. In another embodiment, the encapsulation layer EN may be constituted with multiple layers including an encapsulation organic film and an encapsulation inorganic film.

The encapsulation organic film may include acrylic compounds, epoxy compounds, and the like. The encapsulation organic film may contain, but not limited to, photo-polymerizable organic materials. The encapsulation inorganic film may include, but not limited to, silicon nitride, silicon oxynitride, silicon oxide, titanium oxide, or aluminum oxide.

Meanwhile, although not illustrated, a capping layer, configured to cover the second electrode EL2, may be further interposed between the second electrode EL2 and the encapsulation layer EN.

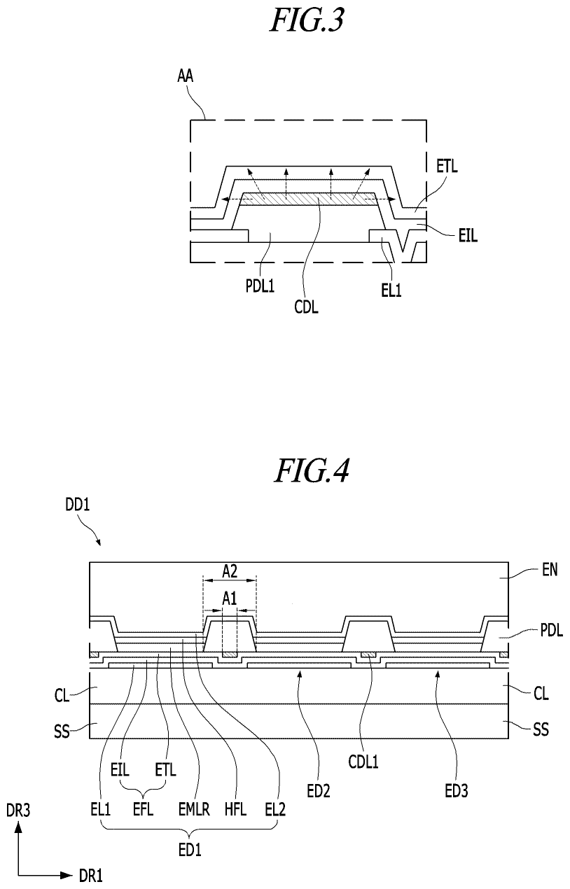

FIG. 3 is an enlarged view of an area demarcated with AA in FIG. 2. Hereinafter, the function of the conductive layer CDL during the acid treatment process will be described with reference to FIGS. 2 and 3.

Compared to acid-treated layers, an electron injection layer and an electron transport layer that have not undergone an acid treatment process may have surface defects. These surface defects may trap holes and electrons, thereby obstructing the movement of the holes and electrons. On the contrary, in an embodiment of the present disclosure, an acid treatment process may be performed after the electron functional layer EFL is formed. The acid treatment process may provide acid components to the substrate SS on which the electron functional layer EFL is formed. The acid components may improve the electron mobility of the electron functional layer EFL through surface modification that heals the surface defects. The surface modification of the electron functional layer EFL through the acid treatment process may improve the light-emitting efficiency of the light-emitting diodes ED1, ED2, ED3.

The acid components provided in the acid treatment process may diffuse into and reach the conductive layer CDL, and the acid components that have reached the conductive layer CDL may re-diffuse into the adjacent electron transport layer ETL and electron injection layer EIL. Since the electron transport layer ETL and the electron injection layer EIL each have an integrated shape, the acid components that have reached the conductive layer CDL may re-diffuse into a portion of the electron transport layer ETL and a portion of the electron injection layer EIL that are disposed within the light-emitting areas PAR, PAG, PAB.

Therefore, the efficiency in surface modification of the display device DD including the conductive layer CDL may be improved through the acid treatment process.

The surface defects of the electron transport layer ETL and the electron injection layer EIL may be improved by the acid components that have been re-diffused by the conductive layer CDL. The electron transport layer ETL and the electron injection layer EIL with improved surface defects may have enhanced electron mobility and hence increased efficiency of electron transport to the light-emitting layers EMLR, EMLG, EMLB. By including the electron functional layer EFL with the surface defects improved, the light-emitting efficiency of the display device DD may be improved.

FIG. 4 is a cross-sectional view of a display device DD1 according to another embodiment of the present disclosure, taken along line I-I′ line of FIG. 2. Referring to FIG. 4, the differences of the display device DD1 from the display device DD described with reference to FIGS. 1 and 2 will be mainly described hereinafter, and any configurations not described hereinafter shall be based on the description of FIG. 2.

Referring to FIG. 4, an electron functional layer EFL may be disposed on a circuit layer CL and a first electrode EL1 and may cover the circuit layer CL and the first electrode EL1. The electron functional layer EFL may include an electron injection layer EIL and an electron transport layer ETL disposed on the electron injection layer EIL. The electron injection layer EIL and the electron transport layer ETL may each have an integrated shape.

A conductive layer CDL1 is disposed on the electron functional layer EFL. In a plan view, the conductive layer CDL1 may be disposed to overlap with a pixel defining film PDL in a plan view. Moreover, the conductive layer CDL1 may directly contact the electron functional layer EFL. In FIG. 4, the conductive layer CDL1 is illustrated with a relatively smaller area than the area of the conductive layer CDL shown in FIG. 2, but the present embodiment is not limited to what is illustrated in FIG. 4. The conductive layer CDL1 may include a conductive material, specifically a metal. Preferably, the conductive layer CDL1 may include a silver-magnesium (AgMg) alloy or silver (Ag).

The pixel defining film PDL may be disposed on the conductive layer CDL1 and the electron functional layer EFL and may be disposed to cover an area between the first electrodes EL1 in a plan view. The pixel defining film PDL may be disposed to correspond to a non-light-emitting area NPA.

Referring to FIG. 4, when viewed from the top, the area A1 of the conductive layer CDL1 may be smaller than the area A2 of the pixel defining film PDL. In a plan view, the conductive layer CDL1 may be completely covered by the pixel defining film PDL.

The pixel defining film PDL may separate the light-emitting layers EMLR, EMLG, EMLB and the hole functional layers HFL for each of the light-emitting diodes ED1, ED2, ED3. In one embodiment, the pixel defining film PDL may prevent the light-emitting layers EMLR, EMLG, EMLB and the hole functional layers HFL, which are formed using an inkjet printing method, from mixing between the light-emitting diodes ED1, ED2, ED3.

Compared to FIG. 2, the display device DD1 described with reference to FIG. 4 has the conductive layer CDL1 interposed between the electron functional layer EFL and the pixel defining film PDL, in the structure having the single pixel defining film PDL, and thus the acid components may be re-diffused from the conductive layer CDL1 after the acid treatment process, thereby enhancing the surface modification efficiency of the electron functional layer EFL.

FIG. 5 is a cross-sectional view of a display device DD2 according to still another embodiment of the present disclosure, taken along line I-I′ line of FIG. 2. Referring to FIG. 5, the differences of the display device DD2 from the display device DD described with reference to FIGS. 1 and 2 will be mainly described hereinafter, and any configurations not described hereinafter shall be based on the description of FIG. 2.

Referring to FIG. 5, a pixel defining film PDL may be disposed on a first electrode EL1 and a conductive layer CL and may be disposed to cover an area between the first electrodes EL1 in a plan view. The pixel defining film PDL may be disposed to correspond to the non-light-emitting area NPA.

A conductive layer CDL2 may be interposed between the pixel defining film PDL and an electron functional layer EFL. Specifically, the conductive layer CDL2 may contact an upper surface of the pixel defining film PDL and a lower surface of an electron injection layer EIL. In FIG. 5, a lower surface of the conductive layer CDL2 is illustrated to have a same area as the upper surface of the pixel defining film PDL, but the present disclosure is not limited to what is illustrated in FIG. 5. In a plan view, the conductive layer CDL2 may be disposed to overlap with the pixel defining film PDL. The conductive layer CDL2 may include a conductive material, specifically a metal. Preferably, the conductive layer CDL2 may include a silver-magnesium (AgMg) alloy or silver (Ag).

The electron functional layer EFL may be disposed on the first electrode EL1 and the conductive layer CDL2 and may cover the first electrode EL1 and the conductive layer CDL2. The electron functional layer EFL may include the electron injection layer EIL and an electron transport layer ETL disposed on the electron injection layer EIL. The electron injection layer EIL and the electron transport layer ETL may each have an integrated shape.

Compared to FIG. 2, the display device DD2 described with reference to FIG. 5 has the conductive layer CDL2 interposed between the pixel defining film PDL and the electron functional layer EFL, in the structure having the single pixel defining film PDL, and thus the acid components may be re-diffused from the conductive layer CDL2 after the acid treatment process, thereby enhancing the surface modification efficiency of the electron functional layer EFL.

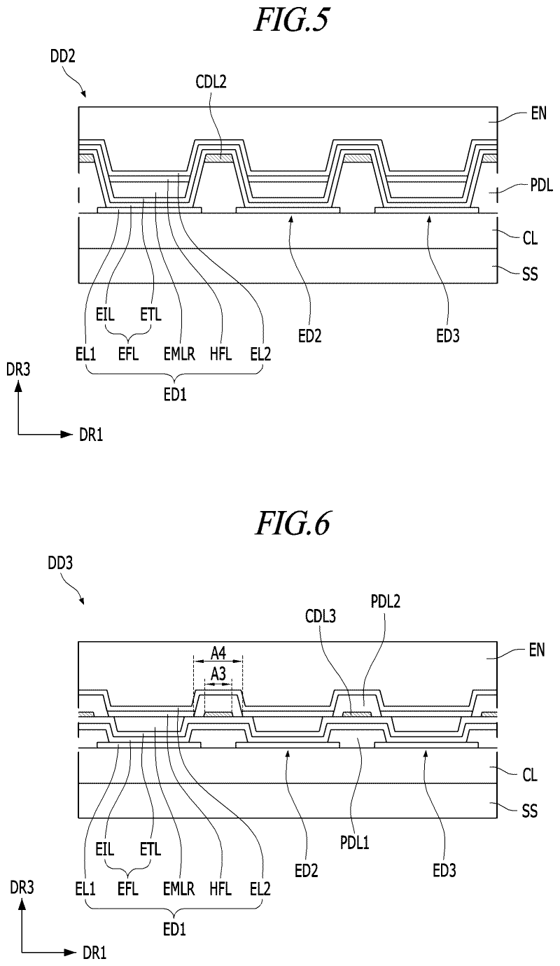

FIG. 6 is a cross-sectional view of a display device DD3 according to yet another embodiment of the present disclosure, taken along line I-I′ line of FIG. 2. Referring to FIG. 6, the differences of the display device DD3 from the display device DD described with reference to FIGS. 1 and 2 will be mainly described hereinafter, and any configurations not described hereinafter shall be based on the description of FIG. 2.

Referring to FIG. 6, a pixel defining film PDL may include a first pixel defining film PDL1 and a second pixel defining film PDL2. The first pixel defining film PDL1 may be disposed on a circuit layer CL and a first electrode EL1 and may be disposed to cover an area between the first electrodes EL1 in a plan view. The second pixel defining film PDL2 may be disposed on an electron functional layer EFL and may be disposed to overlap with the first pixel defining film PDL1.

The electron functional layer may be disposed on the first electrode EL1 and the first pixel defining film PDL1 and may cover the first electrode EL1 and the first pixel defining film PDL1. The electron functional layer EFL may include an electron injection layer EIL and an electron transport layer ETL disposed on the electron injection layer EIL. The electron injection layer EIL and the electron transport layer ETL may each have an integrated shape.

A conductive layer CDL3 may be interposed between the electron functional layer EFL and the second pixel defining film PDL2. Specifically, the conductive layer CDL3 may contact a lower surface of the second pixel defining film PDL2 and an upper surface of the electron transport layer ETL. In a plan view, the conductive layer CDL3 may be disposed to overlap with the first pixel defining film PDL1. Referring to FIG. 6, when viewed from the top, the area A3 of the conductive layer CDL3 may be smaller than the area A4 of the second pixel defining film PDL2. In a plan view, the conductive layer CDL3 may be completely covered by the second pixel defining film PDL2. The conductive layer CDL3 may include a conductive material, specifically a metal. Preferably, the conductive layer CDL3 may include a silver-magnesium (AgMg) alloy or silver (Ag).

The second pixel defining film PDL2 may provide electrical insulation between a second electrode EL2 and the conductive layer CDL3. Moreover, together with the first pixel defining film PDL1, the second pixel defining film PDL2 may separate the light-emitting layers EMLR, EMLG, EMLB and the hole functional layers HFL for each of the light-emitting diodes ED1, ED2, ED3. In one embodiment, the second pixel defining film PDL2 may prevent the light-emitting layers EMLR, EMLG, EMLB and the hole functional layers HFL, which are formed using an inkjet printing method, from mixing between the light-emitting diodes ED1, ED2, ED3.

Compared to FIG. 2, the display device described with reference to FIG. 6 has the conductive layer CDL3 interposed between the second pixel defining film PDL2 and the electron functional layer EFL, thereby allowing the conductive layer CDL3 to be directly exposed to the acid components in the acid treatment process and allowing the acid components to be re-diffused from the conductive layer CDL3 after the acid treatment process to enhance the surface modification efficiency of the electron functional layer EFL.

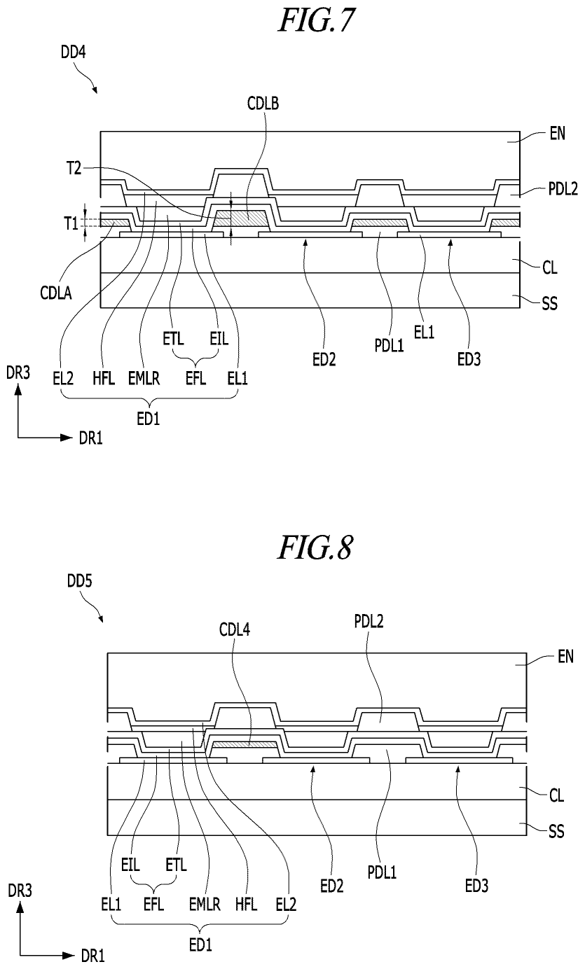

FIG. 7 is a cross-sectional view of a display device DD4 according to still another embodiment of the present disclosure, taken along line I-I′ line of FIG. 2. Referring to FIG. 7, the differences of the display device DD4 from the display device DD described with reference to FIGS. 1 and 2 will be mainly described hereinafter, and any configurations not described hereinafter shall be based on the description of FIG. 2.

Referring to FIG. 7, a conductive layer CDL may include a first conductive layer CDLA and a second conductive layer CDLB. The second conductive layer CDLB may have a third-direction length (referred to as “thickness” hereinafter) that is different from a thickness of the first conductive layer CDLA in the third direction DR3. For instance, the thickness T2 of the second conductive layer CDLB may be greater than the thickness T1 of the first conductive layer CDLA. The first conductive layer CDLA and the second conductive layer CDLB may be interposed between a first pixel defining film PDL1 and an electron functional layer EFL. Specifically, the first conductive layer CDLA and the second conductive layer CDLB may contact an upper surface of the first pixel defining film PDL1 and a lower surface of an electron injection layer EIL. Although it is illustrated in FIG. 7 that lower surfaces of the first conductive layer CDLA and the second conductive layer CDLB each have the same area as the upper surface of the first pixel defining film PDL1, the present embodiment is not limited to this configuration. In a plan view, the first conductive layer CDLA and the second conductive layer CDLB may be disposed to overlap with the first pixel defining film PDL1.

The first conductive layer CDLA and the second conductive layer CDLB may each include a conductive material, specifically a metal. Preferably, the conductive layer CDL may include a silver-magnesium (AgMg) alloy or silver (Ag).

The first pixel defining film PDL1 may be disposed on a circuit layer CL and a first electrode EL1 and may be disposed to cover an area between the first electrodes EL1 in a plan view. The first pixel defining film PDL1 may provide electrical insulation between the first electrode EL1 and the conductive layer CDL disposed on the first pixel defining film PDL1.

The electron functional layer EFL may be disposed on the first electrode EL1 and the first pixel defining film PDL1 and may cover the first electrode EL1 and the first pixel defining film PDL1. The electron functional layer EFL may further include an electron injection layer EIL and an electron transport layer ETL disposed on the electron injection layer EIL. The electron injection layer EIL and the electron transport layer ETL may each have an integrated shape.

The display device DD4 in accordance with an embodiment of the present disclosure may further include a second pixel defining film PDL2. The second pixel defining film PDL2 may be disposed on the electron functional layer EFL and may be disposed to cover an area between the first electrodes EL1 in a plan view. The second pixel defining film PDL2 may be disposed to correspond to a non-light-emitting area NPA.

The second pixel defining film PDL2 may define light-emitting layers EMLR, EMLG, EMLB and hole functional layers HFL formed between the pixel defining films PDL within corresponding light-emitting diodes ED1, ED2, ED3. In one embodiment, the second pixel defining film PDL2 may prevent the light-emitting layers EMLR, EMLG, EMLB and the hole functional layers HFL, which are formed using an inkjet printing method, from mixing between the light-emitting diodes ED1, ED2, ED3. Nonetheless, the present disclosure is not limited to this configuration, and it is possible that the functions of the second pixel defining film PDL2 are performed by the first pixel defining film PDL1 and the second pixel defining film PDL2 is omitted.

Compared to FIG. 2, the display device DD4 described with reference to FIG. 7 includes the first conductive layer CDLA and the second conductive layer CDLB, thereby allowing some areas of the electron functional layer EFL adjacent to light-emitting areas PAR, PAG, PAB to have different surface modification efficiencies, respectively, through the acid treatment process. For instance, the first conductive layer CDLA and the second conductive layer CDLB may have different thicknesses, and the acid components may have different re-diffusion ratios in the first conductive layer CDLA and the second conductive layer CDLB during the acid treatment process. The re-diffusion ratio of an acid component may be a ratio of an amount of the re-diffused acid component from a conductive layer to an amount of the acid component reaching the conductive layer.

Therefore, different amounts of acid components may reach some areas of the electron functional layer EFL disposed, respectively, in the light-emitting areas PAR, PAG, PAB, thereby resulting in different surface modification efficiencies. Specifically, referring to FIG. 7, the red light-emitting area PAR and the green light-emitting area PAG are adjacent to the second conductive layer CLDB, and the blue light-emitting area PAB is adjacent to the first conductive layer CDLA. Therefore, a relatively larger amount of acid components may reach the electron functional layer EFL disposed in the red light-emitting area PAR and the green light-emitting area PAG than the electron functional layer EFL disposed in the blue light-emitting area PAB.

In an embodiment, the relatively thicker second conductive layer CDLB may have a higher re-diffusion ratio of acid components than the first conductive layer CDLA.

Although it is illustrated in FIG. 7 that the second conductive layer CDLB is interposed between the red light-emitting area PAR and the green light-emitting area PAG and the first conductive layer CDLA is interposed between the green light-emitting area PAG and the blue light-emitting area PAB and between the red light-emitting area PAR and the blue light-emitting area PAB, the present embodiment is not necessarily limited to this configuration. For example, the thicknesses of the conductive layers CDL disposed between the light-emitting areas PAR, PAG, PAB may be different from one another regardless of the color of the light-emitting area.

FIG. 8 is a cross-sectional view of a display device DD5 according to yet another embodiment of the present disclosure, taken along line I-I′ line of FIG. 2. Referring to FIG. 8, the differences of the display device DD5 from the display device DD described with reference to FIGS. 1 and 2 will be mainly described hereinafter, and any configurations not described hereinafter shall be based on the description of FIG. 2.

Referring to FIG. 8, a conductive layer CDL4 may be disposed on a first pixel defining film PDL1, but the conductive layer CDL4 may overlap with one or more first pixel defining films PDL1 and may not overlap with other first pixel defining films PDL1. For instance, the conductive layer CDL4 may be disposed on the first pixel defining film PDL1 interposed between a red light-emitting area PAR and a green light-emitting area PAG and may not be disposed on the first pixel defining film PDL1 interposed between the green light-emitting area PAG and a blue light-emitting area PAB and the first pixel defining film PDL1 between the blue light-emitting area PAB and the red light-emitting area PAR.

The conductive layer CDL4 may be interposed between the first pixel defining film PDL1 and an electron functional layer EFL. Specifically, the conductive layer CDL4 may contact an upper surface of the first pixel defining film PDL1 and a lower surface of an electron injection layer EIL. Although it is illustrated in FIG. 8 that a lower surface of the conductive layer CDL4 has the same area as the upper surface of the first pixel defining film PDL1, the present embodiment is not limited to what is illustrated in FIG. 8.

The first pixel defining film PDL1 may be disposed on a circuit layer CL and a first electrode EL1 and may be disposed to cover an area between the first electrodes EL1 in a plan view. The first pixel defining film PDL1 may provide electrical insulation between the first electrode EL1 and the conductive layer CDL4 disposed on the first pixel defining film PDL1.

The electron functional layer EFL may be disposed on the first electrode EL1, the conductive layer CDL4 and the first pixel defining film PDL1 and may cover the first electrode EL1, the conductive layer CDL4 and the first pixel defining film PDL1. The electron functional layer EFL may further include an electron injection layer EIL and an electron transport layer ETL disposed on the electron injection layer EIL. The electron injection layer EIL and the electron transport layer ETL may each have an integrated shape.

The display device DD5 in accordance with an embodiment of the present disclosure may further include a second pixel defining film PDL2. However, the embodiment is not necessarily limited to this configuration, and the second pixel defining film PDL2 may be omitted. The second pixel defining film PDL2 may be disposed on the electron functional layer EFL and may be disposed between the first electrodes EL1. The second pixel defining film PDL2 may be disposed to correspond to a non-light-emitting area NPA.

Together with the first pixel defining film PDL1, the second pixel defining film PDL2 may separate light-emitting layers EMLR, EMLG, EMLB and hole functional layers HFL for respective light-emitting diodes ED1, ED2, ED3. In one embodiment, the second pixel defining film PDL2 may prevent the light-emitting layers EMLR, EMLG, EMLB and the hole functional layers HFL, which are formed using an inkjet printing method, from mixing between the light-emitting diodes ED1, ED2, ED3.

Compared to FIG. 2, the display device DD5 described with reference to FIG. 8 has the conductive layer CDL4 disposed to overlap with certain first pixel defining films PDL1 and not to overlap with other first pixel defining films PDL1, thereby allowing some areas of the electron functional layer EFL adjacent to respective light-emitting areas PAR, PAG, PAB to have different surface modification efficiencies through the acid treatment process.

For example, some of the light-emitting areas PAR, PAG, PAB may have the conductive layer CDLA interposed therebetween. A relatively larger amount of acid components re-diffused from the conductive layer CDL4 may reach an area of the electron functional layer EFL that is adjacent to the conductive layer CDL4, and a relatively smaller amount of acid components may reach an area of the electron functional layer EFL that is relatively far from the conductive layer CDL4. Therefore, the areas of the electron functional layer EFL disposed in the light-emitting areas may have different surface modification efficiencies depending on the relative distance from the conductive layer CDL4.

Although it is illustrated in FIG. 8 that the conductive layer CDL4 is included in an area between the red light-emitting area PAR and the green light-emitting area PAG, the embodiment is not limited to this illustration. For example, the conductive layer CDL4 may be disposed in one or more areas between the light-emitting areas PAR, PAG, PAB.

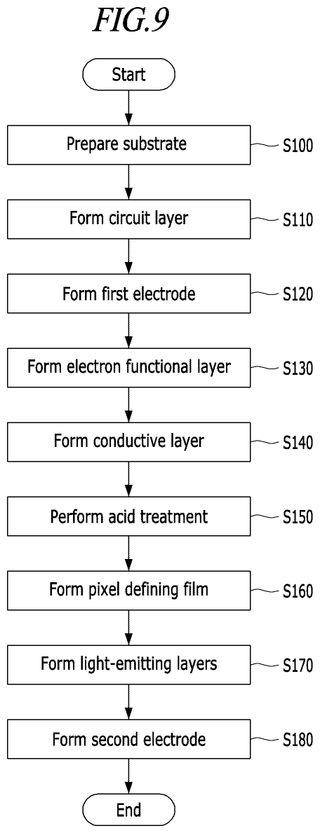

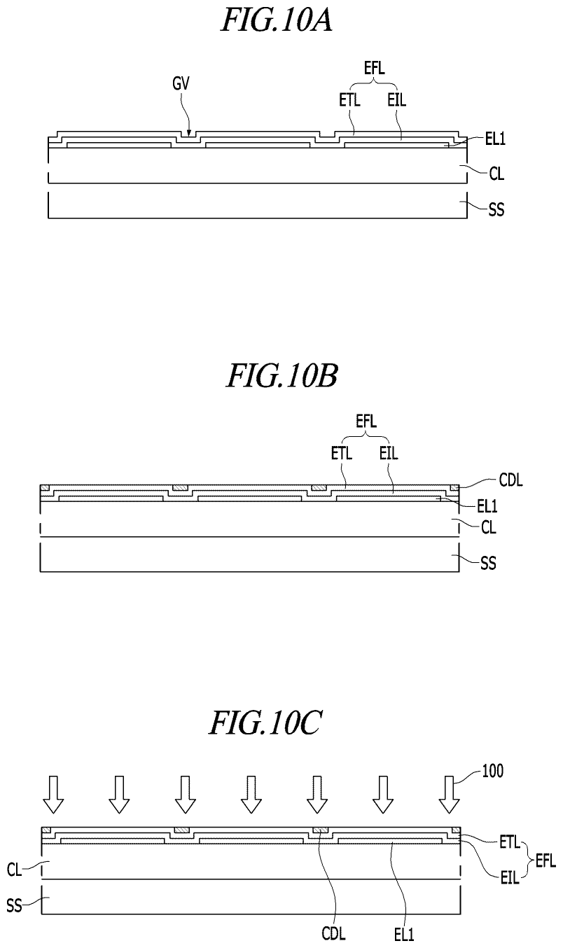

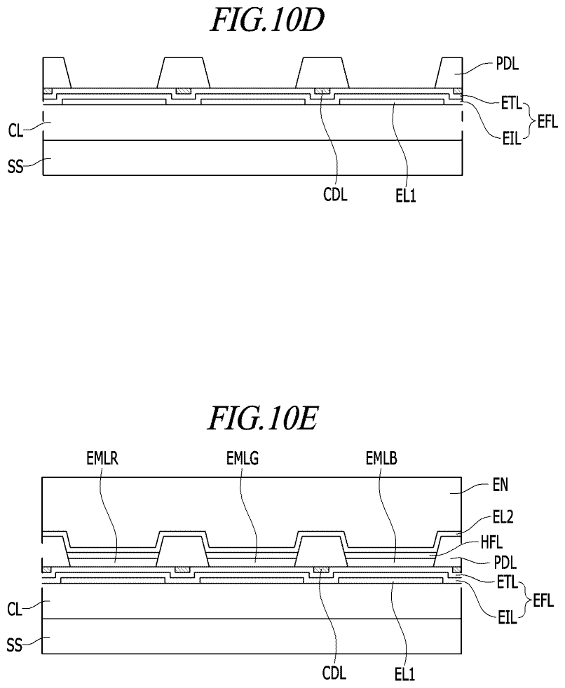

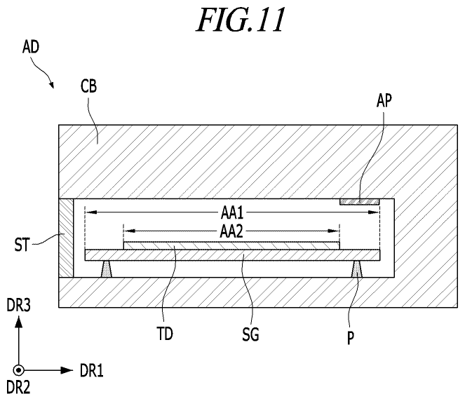

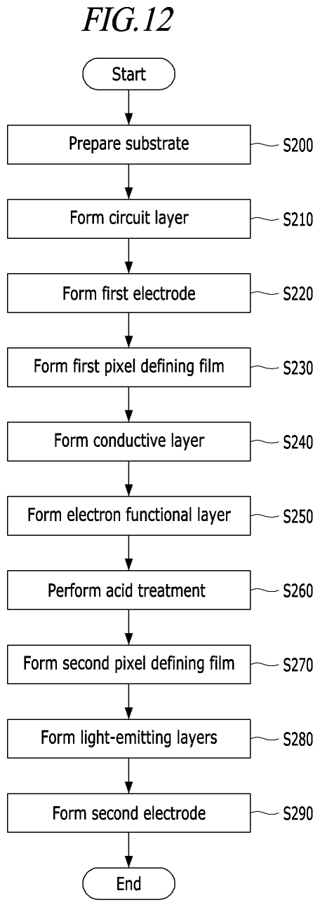

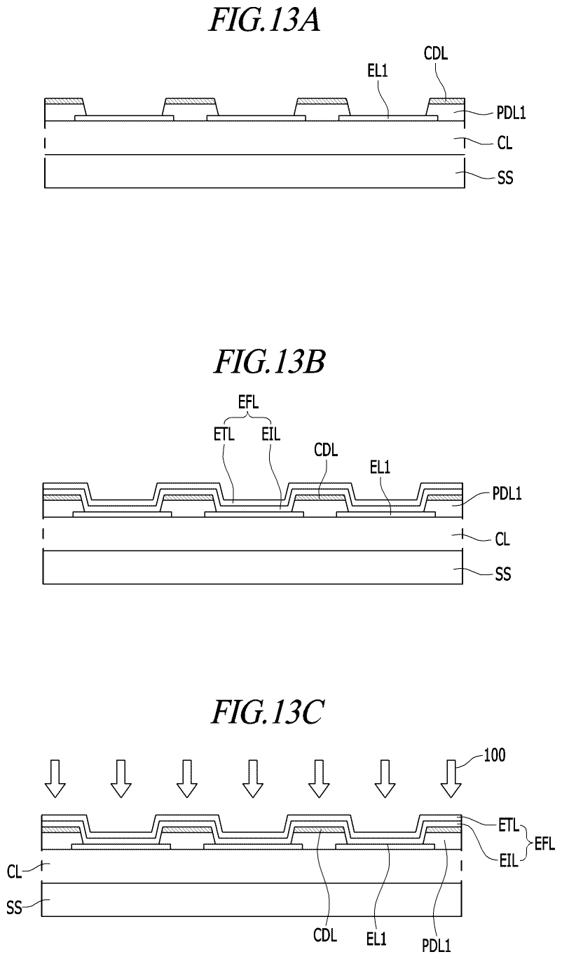

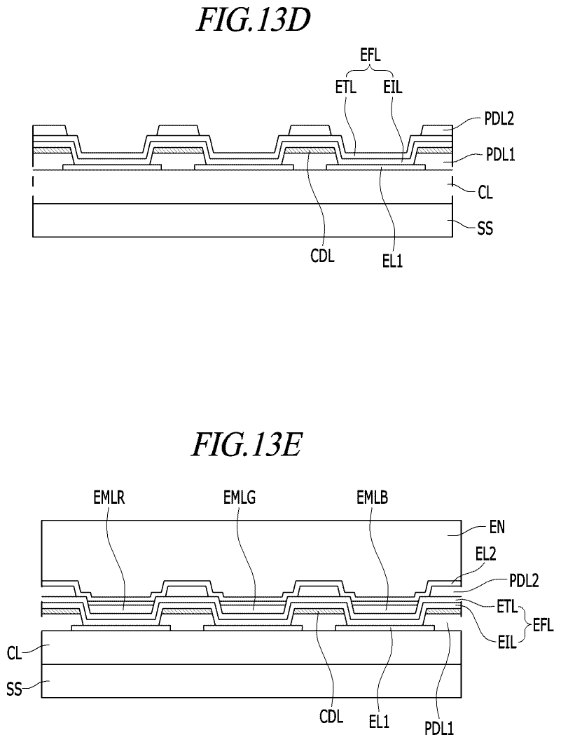

FIG. 9 and FIG. 12 are each a flow diagram illustrating a method of manufacturing a display device according to an embodiment of the present disclosure. FIG. 10 and FIG. 13 are each brief illustrations of the steps involved in the method of manufacturing a display device according to an embodiment of the present disclosure. FIG. 11 shows an acid treatment apparatus AD according to an embodiment of the present disclosure.

Hereinafter, a method of manufacturing a display device in accordance with an embodiment of the present disclosure will be described with reference to FIGS. 9 and 10. Any elements described with reference to FIGS. 2 to 8 are noted with same reference numerals but will not be redundantly described hereinafter.

Referring to FIG. 9, the method of manufacturing a display device in accordance with one embodiment of the present disclosure may include: preparing a substrate (S100); forming a circuit layer (S110); forming a first electrode (S120); forming an electron functional layer (S130); forming a conductive layer (S140); performing acid treatment (S150); forming a pixel defining film (S160); forming light-emitting layers (S170); and forming a second electrode (S180).

Referring to FIGS. 9 and 10A, in the preparing of the substrate (S100), a substrate SS may be prepared. In the forming of the circuit layer (S110), a circuit layer CL may be formed on the prepared substrate SS. In the forming of the first electrode (S120), a first electrode EL1 may be formed on the circuit layer CL. In one embodiment, in the forming of the electron functional layer (S130), an electron injection layer EIL may be formed on the first electrode EL1 to cover the first electrode EL1, and an electron transport layer ETL may be formed on the electron injection layer EIL. The electron injection layer EIL and the electron transport layer ETL may each be formed through a full-face deposition process. In an embodiment, the electron functional layer EFL may have a groove GV formed in between the first electrodes EL. Nevertheless, the embodiment is not limited to such a configuration.

Referring to FIGS. 9 and 10B, in the forming of the conductive layer (S140), a conductive layer CDL may be formed on the electron functional layer EFL. In an embodiment, the conductive layer CDL may be formed by, but not limited to, an inkjet printing technique to be disposed in the groove GV of the electron functional layer EFL. For instance, the conductive layer CDL may be formed using a photolithography technique.

Referring to FIGS. 9 and 10C, the performing of the acid treatment (S150) may include a process of providing an acid component to the electron functional layer EFL. In an embodiment, in the performing of the acid treatment (S150), the acid component may be diffused into the electron functional layer EFL by creating a predetermined concentration of acidic environment 100 on the substrate SS. For example, in the performing of the acid treatment (S150), a liquid or gas containing acid components may be provided to the substrate SS.

The acid components may be configured to improve the electron mobility of the electron functional layer EFL through surface modification that heals the surface defects of the electron functional layer EFL. Achieving the surface modification of the electron functional layer EFL through the acid treatment (S150) may lead to an improved light-emitting efficiency of the light-emitting diodes.

The acid components provided in the acid treatment (S150) may diffuse into and reach the conductive layer CDL, and the acid components that have reached the conductive layer CDL may re-diffuse into the adjacent electron transport layer ETL and electron injection layer EIL. Since the electron transport layer ETL and the electron injection layer EIL each have an integrated shape, the acid components that have reached the conductive layer CDL may re-diffuse into a portion of the electron transport layer ETL and a portion of the electron injection layer EIL that are disposed within the light-emitting areas. Therefore, the display device including the conductive layer CDL may have the surface modification efficiency enhanced through the acid treatment process.

The surface defects of the electron transport layer ETL and the electron injection layer EIL may be improved by the acid components that have been re-diffused by the conductive layer CDL. The electron transport layer ETL and the electron injection layer EIL with improved surface defects may have an enhanced electron mobility and hence an increased efficiency of electron transport to the light-emitting layers EMLR, EMLG, EMLB.

Referring to FIGS. 9 and 10D, in the forming of the pixel defining film (S160), a pixel defining film PDL may be formed on the electron transport layer ETL and the conductive layer CDL. The forming of the pixel defining film (S160) may include forming the pixel defining film PDL not only to cover an area between the first electrons EL but also to correspond to a non-light-emitting area NPA.

Referring to FIGS. 9 and 10E, in the forming of the light-emitting layers (S170), light-emitting layers EMLR, EMLG, EMLB may be formed in between the pixel defining films PDL. The light-emitting layers EMLR, EMLG, EMLB may be formed to correspond, respectively, to light-emitting areas PAR, PAG, PAB.

In an embodiment of the present disclosure, the performing of the acid treatment (S150) is described, as an example, to be carried out between the forming of the conductive layer (S140) and the forming of the pixel defining film (S160), but the present disclosure is not limited to this example, and it is possible that the performing of the acid treatment (S150) is carried out after the forming of the pixel defining film (S160) in another embodiment.

In an embodiment, the light-emitting layers EMLR, EMLG, EMLB may contain an organic light-emitting material. Since organic light-emitting materials are vulnerable to acid components, the light-emitting layers EMLR, EMLG, EMLB may be damaged when the light-emitting layers EMLR, EMLG, EMLB containing organic diodes are directly exposed to the acid components.

In a display device according to a comparative example, a first electrode that is relatively adjacent to a circuit layer may function as a cathode, and a second electrode disposed above the first electrode with a light-emitting layer interposed between the first and second electrodes may function as an anode. In a comparative example, the forming of the electron functional layer may be carried out after the forming of the light-emitting layer, resulting in forming the electron functional layer above the light-emitting layer. Here, since the performing of the acid treatment is carried out after the forming of the electron functional layer, the acid components may be diffused to the light-emitting layer, causing a damage to the light-emitting layer.

Unlike the comparative example, in an embodiment of the present disclosure, the forming of the light-emitting layers (S170) is carried out after the performing of the acid treatment (S150), and thus it is possible to reduce the damage to the light-emitting layers EMLR, EMLG, EMLB caused by the acid components.

In the forming of the second electrode (S180), a second electrode EL2 may be formed on the pixel defining film PDL and a hole functional layer HFL.

In an embodiment of the present disclosure, the steps described with reference to FIG. 9 may be partially modified. For example, the forming of the pixel defining film (S160) may be carried out after the forming of the first electrode (S120), followed by the forming of the conductive layer (S140) and then the forming of the electron functional layer (S130). In other words, in a method of manufacturing a display device in accordance with another embodiment (now shown) may be processed by sequentially performing the steps of: preparing a substrate (S100); forming a circuit layer (S110); forming a first electrode (S120); forming a pixel defining film (S160); forming a conductive layer (S140); forming an electron functional layer (S130); performing acid treatment (S150); forming light-emitting layers (S170); and forming a second electrode (S180). According to this modified embodiment, the conductive layer may be interposed between the pixel defining film and the electron functional layer and may directly contact the electron functional layer, as shown in FIG. 5.

Illustrated in FIG. 11 is an acid treatment apparatus AD, in which the performing of the acid treatment (S150) may be carried out, according to an embodiment of the present disclosure. The acid treatment apparatus AD may include an acid treatment chamber CB, an acid providing device AP, a sealing shutter ST, a plurality of pins P, and a stage SG.

The acid treatment chamber CB may be configured to provide a space for carrying out the performing of the acid treatment (S150) of the display device DD. The acid treatment chamber CB may include stainless steel (SUS) or fluorine-based plastic materials to withstand acid corrosion.

The acid providing device AP may be disposed on an inner wall of the acid treatment chamber CB. Although an example is illustrated in FIG. 11 in which the acid providing device AP is disposed at one side of an upper wall of the inner wall of the acid treatment chamber CB, the present disclosure is not limited to this example, and it is possible that the acid providing device AP is disposed at various locations.

The acid providing device AP may be configured to provide acid components into the acid treatment chamber CB. In an embodiment, the acid treatment chamber CB may further include an acid concentration sensor (not shown) configured to measure the concentration of the acid components in the acid treatment chamber CB, and the acid providing device AP may be configured to adjust the supply amount of the acid components to maintain a constant concentration of the acid components in the acid treatment chamber CB based on the acid concentration data in the acid treatment chamber CB measured by the acid concentration sensor (not shown).

The sealing shutter ST may be disposed on one side of the acid treatment chamber CB. The sealing shutter ST may serve as a door device configured to open and close the acid treatment chamber CB. By opening or closing the acid treatment chamber CB by use of the sealing shutter ST, materials may be prevented from being exchanged in and out of the acid treatment chamber CB.

The plurality of pins P may be positioned at the bottom of the acid treatment chamber CB. The plurality of pins P may include at least two or more pins. The plurality of pins P may be configured to support the stage SG. The third-direction lengths (“heights” hereinafter) of the plurality of pins P may be extended and shortened, allowing the heights of the plurality of pins P to be adjusted and thus allowing the height of the stage SG to be adjusted.

The stage SG may be disposed on the plurality of pins P and secured by the plurality of pins P. The stage SG may be configured to support an acid treatment target substrate TD, which may be an intermediate product of the display device DD including the electron functional layer EFL and the conductive layer CDL performed up to step S140.

In an embodiment, the acid treatment target substrate TD formed before performing step S150 in FIG. 9 is transported onto the stage SG inside the acid treatment chamber CB through the sealing shutter ST and then is acid treated in step S150. After the acid treatment in step S150 is completed, the acid treatment target substrate TD may be transported out of the acid treatment chamber CB through the sealing shutter ST.

Owing to the plurality of pins P, the stage SG may maintain its horizontal orientation in the third direction DR3. In one embodiment, the area AA1 of the stage SG in the first direction DR1 and second direction DR2 may be larger than the area AA2 of the display device DD.

Hereinafter, a method of manufacturing a display device DD in accordance with another embodiment of the present disclosure will be described with reference to FIGS. 12 and 13. Any elements described with reference to FIGS. 2 to 8 are noted with same reference numerals but will not be redundantly described hereinafter.

Referring to FIG. 12, the method of manufacturing a display device in accordance with another embodiment of the present disclosure may include: preparing a substrate (S200); forming a circuit layer (S210); forming a first electrode (S220); forming a first pixel defining film (S230); forming a conductive layer (S240); forming an electron functional layer (S250); performing acid treatment (S260); forming a second pixel defining film (S270); forming light-emitting layers (S280); and forming a second electrode (S290).

Referring to FIGS. 12 and 13A, in the preparing of the substrate (S200), a substrate SS may be prepared. In the forming of the circuit layer (S210), a circuit layer CL may be formed on the prepared substrate SS. In the forming of the first electrode (S220), a first electrode EL1 may be formed on the circuit layer CL according to a pattern in which light-emitting diodes ED1, ED2, ED3 are disposed. In the forming of the first pixel defining film, a first pixel defining film PDL1 may be formed on the circuit layer CL and the first electrode EL1. The first pixel defining film PDL1 may be formed to cover an area between the first electrodes EL1 in a plan view. The first pixel defining film PDL1 may be formed to correspond to a non-light-emitting area NPA.

In the forming of the conductive layer (S240), a conductive layer CDL may be formed on the first pixel defining film PDL1. Specifically, the conductive layer CDL may be formed to directly contact an upper surface of the first pixel defining film PDL1. Although it is illustrated in FIG. 12A that a lower surface of the conductive layer CDL has the same area as the upper surface of the first pixel defining film PDL1, the embodiment is not limited to what is illustrated in FIG. 12A. In an embodiment, the conductive layer CDL may be formed through a separate patterning process from the first pixel defining film PDL1. The conductive layer CDL may be formed to have a smaller area than, and completely covered by, the first pixel defining film PDL1 in a plan view.

Referring to FIGS. 12 and 13B, in the forming of the electron functional layer (S250), an electron injection layer EIL may be formed on the first electrode EL1 and the conductive layer CDL, and an electron transport layer ETL may be formed on the electron injection layer EIL. The electron injection layer EIL and the electron transport layer ETL may each be formed as an integrated shape.

Referring to FIGS. 12 and 13C, the performing of the acid treatment (S260) may include a process of providing an acid component to the electron functional layer EFL. In an embodiment, in the performing of the acid treatment (S260), the acid component may be diffused into the electron functional layer EFL by, but not limited to, creating a predetermined concentration of acidic environment 100 on the substrate SS. For example, in the performing of the acid treatment (S260), a liquid or gas containing acid components may be provided to the substrate SS.

The acid components may be configured to improve the electron mobility of the electron functional layer EFL through surface modification that heals the surface defects of the electron functional layer EFL. Achieving the surface modification of the electron functional layer EFL through the acid treatment (S260) may lead to an improved light-emitting efficiency of the light-emitting diodes.

The acid components provided in the acid treatment (S260) may diffuse into and reach the conductive layer CDL, and the acid components that have reached the conductive layer CDL may re-diffuse into the adjacent electron transport layer ETL and electron injection layer EIL. Since the electron transport layer ETL and the electron injection layer EIL each have an integrated shape, the acid components that have reached the conductive layer CDL may re-diffuse into a portion of the electron transport layer ETL and a portion of the electron injection layer EIL that are disposed within the light-emitting areas. Therefore, the display device including the conductive layer CDL may have the surface modification efficiency enhanced through the acid treatment process.

The surface defects of the electron transport layer ETL and the electron injection layer EIL may be improved by the acid components that have been re-diffused by the conductive layer CDL. The electron transport layer ETL and the electron injection layer EIL with improved surface defects may have an enhanced electron mobility and hence an increased efficiency of electron transport to the light-emitting layers EMLR, EMLG, EMLB.

Referring to FIGS. 12 and 13D, in the forming of the second pixel defining film (S270), a second pixel defining film PDL2 may be formed on a portion of the electron transport layer ETL. The second pixel defining film PDL2 may be formed to correspond to the non-light-emitting area NPA.

In the present embodiment, the performing of the acid treatment (S260) is described, as an example, to be carried out between the forming of the electron functional layer (S250) and the forming of the second pixel defining film (S270), but the present disclosure is not limited to this example, and it is possible that the performing of the acid treatment (S260) is carried out after the forming of the second pixel defining film (S270) in a different embodiment.

Referring to FIGS. 12 and 13E, in the forming of the light-emitting layers (S280), light-emitting layers EMLR, EMLG, EMLB may be formed to correspond, respectively, to light-emitting areas PAR, PAG, PAB.

In an embodiment, the light-emitting layers EMLR, EMLG, EMLB may contain an organic light-emitting material. Since organic light-emitting materials are vulnerable to acid components, the light-emitting layers EMLR, EMLG, EMLB may be damaged when the light-emitting layers EMLR, EMLG, EMLB containing the organic light-emitting material are directly exposed to the acid components.

In a display device according to a comparative example, the forming of the electron functional layer EFL may be processed after the forming of the light-emitting layers such that the electron functional layer EFL is formed on the light-emitting layers EMLR, EMLG, EMLB. Here, since the performing of the acid treatment is processed after the forming of the electron functional layer, the acid components may be diffused to the light-emitting layers EMLR, EMLG, EMLB, causing a damage to the light-emitting layers EMLR, EMLG, EMLB.

Unlike the comparative example, in an embodiment of the present disclosure, the forming of the light-emitting layers (S280) is carried out after the performing of the acid treatment (S260), and thus it is possible to reduce the damage to the light-emitting layers EMLR, EMLG, EMLB caused by the acid components.

In the forming of the second electrode (S290), a second electrode EL2 may be formed on the second pixel defining film PDL2 and a hole functional layer HFL.

While certain embodiments of the present disclosure have been described above, anyone ordinarily skilled in the art to which the present disclosure pertains shall appreciate that there may be a variety of modifications and permutations of the present disclosure without departing from the technical ideas and scopes of the present disclosure that are defined in the appended claims. Moreover, it shall be appreciated that the disclosed embodiments are not intended to restrict the present disclosure thereto and that every technical idea within the appended claims and their equivalents is interpreted to be included in the scope of the present disclosure.

What is claimed is:

1. A display device comprising:
a substrate;
a circuit layer disposed on the substrate;
a plurality of first electrodes disposed on the circuit layer and spaced apart from each other;
a pixel defining film disposed on the circuit layer and disposed to cover an area between the first electrodes in a plan view;
a conductive layer disposed to overlap with the pixel defining film in the plan view;
an electron functional layer disposed on the first electrodes and covering the first electrodes in the plan view and in direct contact with the conductive layer;
a light-emitting layer disposed on the electron functional layer; and
a second electrode disposed on the light-emitting layer.

2. The display device of claim 1, wherein the conductive layer comprises a metal.

3. The display device of claim 1, wherein the conductive layer comprises at least one of a silver-magnesium (AgMg) alloy or silver (Ag).

4. The display device of claim 1, wherein the electron functional layer comprises metal oxide.

5. The display device of claim 4, wherein the electron functional layer comprises at least one of an electron injection layer comprising zinc oxide (ZnO) or an electron transport layer comprising zinc-magnesium oxide (ZnMgO).

6. The display device of claim 5, wherein each of the electron transport layer and the electron injection layer has an integrated shape.

7. The display device of claim 1, wherein the conductive layer is interposed between the pixel defining film and the electron functional layer and directly contacts the pixel defining film and the electron functional layer.

8. The display device of claim 1, wherein:
the pixel defining film comprises a first pixel defining film and a second pixel defining film;
the first pixel defining film is disposed on the first electrodes and disposed to cover the area between the first electrodes in the plan view;
the second pixel defining film is disposed on the first pixel defining film and the electron functional layer and overlaps with the first pixel defining film in the plan view; and
the conductive layer is interposed between the first pixel defining film and the second pixel defining film.

9. The display device of claim 8, wherein the conductive layer is interposed between the first pixel defining film and the electron functional layer and directly contacts the first pixel defining film and the electron functional layer.

10. The display device of claim 8, wherein the conductive layer is interposed between the electron functional layer and the second pixel defining film and directly contacts the electron functional layer and the second pixel defining film.

11. The display device of claim 1, wherein:
the pixel defining film is provided in plurality in the plan view;
the conductive layer comprises a first conductive layer and a second conductive layer disposed on different pixel defining films of the plurality of pixel defining films; and
the first conductive layer and the second conductive layer have different thicknesses from each other.

12. The display device of claim 1, wherein:
the pixel defining film is provided in plurality in the plan view;
the conductive layer overlaps with at least one pixel defining film of the plurality of pixel defining films and does not overlap with the other pixel defining films of the plurality of pixel defining films in the plan view.

13. The display device of claim 1, wherein the light-emitting layer comprises a quantum dot.

14. A method of manufacturing a display device, the method comprising:
preparing a substrate defined with a light-emitting area and a non-light-emitting area;
forming a circuit layer on the substrate;
forming first electrodes on the circuit layer to correspond to the light-emitting area;
forming an electron functional layer to cover the first electrodes in a plan view;
forming a pixel defining film to correspond to the non-light-emitting area and to cover an area between the first electrodes;
forming a conductive layer to correspond to the area between the first electrodes;
acid treating the electron functional layer;
forming a light-emitting layer on the electron functional layer; and
forming a second electrode on the light-emitting layer.

15. The method of claim 14, wherein the forming of the light-emitting layer is processed after the acid treating of the electron functional layer.

16. The method of claim 14, wherein the conductive layer is formed using silver (Ag) or an AgMg alloy.

17. The method of claim 14, wherein the forming of the electron functional layer comprises:
forming an electron injection layer using ZnO; and
forming an electron transport layer using ZnMgO.

18. The method of claim 14, wherein:
the forming of the conductive layer is performed after the forming of the electron functional layer;
the acid treating of the electron functional layer is performed after the forming of the conductive layer;
the forming of the pixel defining film is performed after the acid treating of the electron functional layer; and
the conductive layer is formed to directly contact the electron functional layer and the pixel defining film.

19. The method of claim 14, wherein:
the forming of the pixel defining film comprises forming a first pixel defining film and forming a second pixel defining film;
the forming of the first pixel defining film is performed after the forming of the first electrodes;
the forming of the conductive layer is performed after the forming of the first pixel defining film;
the forming of the electron functional layer is performed after the forming of the conductive layer; and
the forming of the second pixel defining film is performed after the acid treating of the electron functional layer.

20. A display device comprising:
a substrate;
a circuit layer disposed on the substrate;
a plurality of first electrodes disposed on the circuit layer and spaced apart from each other;
a pixel defining film disposed on the circuit layer and disposed to cover an area between the first electrodes in the plan view;
a conductive layer disposed to overlap with the pixel defining film in the plan view;
an electron functional layer disposed on the first electrodes and covering the first electrodes in the plan view;
a light-emitting layer disposed on the first electrodes; and
a second electrode disposed to face the first electrodes with the light-emitting layer between the second electrode and the first electrodes,
wherein the conductive layer comprises at least one of an AgMg alloy or silver (Ag), and
wherein the electron functional layer comprises:
an electron injection layer comprising ZnO; and
an electron transport layer disposed on the electron injection layer and comprising ZnMgO.
